(19) United States
(12) Patent Application Publication
(10) Pub. No.: US 2010/0136773 A1
(43) Pub. Date: Jun. 3, 2010

(54) Semiconductor Device Manufacturing Method and Substrate Processing Apparatus

(76) Inventors: Naonori Akae, Toyama (JP); Masahiro Yonebayashi, Toyama (JP); Tsukasa Kamakura, Toyama (JP); Yoshiro Hirose, Toyama (JP)

Correspondence Address: KRATZ, QUINTOS & HANSON, LLP, 1420 K Street, N.W., 4th Floor, WASHINGTON, DC, 20005, US

(21) Appl. No.: 11/990,120

(22) PCT Filed: Aug. 4, 2006
(86) PCT No.: PCT/JP2006/315476

§ 371 Date: Apr. 22, 2008

(30) Foreign Application Priority Data
Aug. 10, 2005 (JP) 2005-232567

(51) Int. Cl. H01L 21/365; H01L 21/443; H01L 21/469

(52) U.S. Cl. 438/507; 438/680; 438/778; 118/729; 257/E21.463; 257/E21.478; 257/E21.487

(57) ABSTRACT

A semiconductor device manufacturing method comprises the steps of loading a substrate into a processing chamber, mounting the substrate on a support tool in the processing chamber, processing the substrate mounted on the support tool by supplying process gas into the processing chamber, purging the interior of the processing chamber after the substrate processing step, and unloading the processed substrate from the processing chamber after the step of purging the interior of the processing chamber, wherein in the step of purging the interior of the processing chamber, exhaust is performed toward above the substrate and toward below the substrate in the processing chamber, and the exhaust rate toward above the substrate is set larger than the exhaust rate toward below the substrate.

### TECHNICAL FIELD

The present invention relates to a semiconductor device manufacturing method including a process for performing a preferred processing on a substrate using gas and a substrate processing apparatus utilized in that method, and relates in particular to technology for purging gas remaining after processing, and for example, is effective in use for a CVD apparatus for forming a thin film such as oxidized film or semiconductor film or metallic film on a semiconductor wafer (hereinafter called “wafer”) on which IC is fabricated in semiconductor integrated circuit devices (hereinafter called “IC”).

### BACKGROUND ART

A single-wafer type cold wall CVD apparatus (hereinafter called “single-wafer CVD apparatus”) is utilized in IC manufacturing method to form a thin film such as oxidized film or semiconductor film or metallic film on the wafer.

The single-wafer CVD apparatus generally includes a processing chamber to hold the wafer serving as the substrate for processing, a susceptor to hold one wafer at a time in this processing chamber, a heating unit for heating the wafer held in the susceptor, a gas head for supplying the process gas to the wafer supported on the susceptor, and an exhaust port for exhausting the processing chamber. Refer for example to patent document 1.
Patent document 1: Japanese Patent Non-Examined Publication No. 2002-212729

### DISCLOSURE OF INVENTION

### Problems to be Solved by Invention

When forming amorphous silicon film using this type of single-wafer CVD apparatus, the processing must be performed at a low temperature (400 to 800° C.).

When monosilane (SiH₄) gas was utilized in processing in a region (500 to 800° C.) with a large activation energy at this low temperature, the uniformity of film thickness distribution within the wafer surface declined due to being easily susceptible to effects from the wafer surface temperature distribution.

Also, when disilane (Si₂H₆) gas was utilized in processing in a region (400 to 700° C.) with a small activation energy at this low temperature, the uniformity of film thickness distribution within the wafer surface improved compared to using monosilane gas since there was little effect from the wafer surface temperature distribution.

However, when using disilane gas to process in a region with a small activation energy, the uniformity of film thickness distribution within the wafer surface is easily affected by the gas flow since processing in this region is greatly affected by the gas flow.

Utilizing this type of CVD apparatus of the conventional art to process in a region with little activation energy creates the problem that the uniformity of film thickness distribution within the wafer surface deteriorates because the purge efficiency for expelling residual gases within the processing chamber is poor, so gas components remaining after the film forming react with the wafer surface.

Another problem is that gas components remaining after film-forming reacts with the heater surface of the heating unit, causing deterioration in the heater.

The present invention has an object of providing a substrate processing apparatus and a semiconductor device manufacturing method for preventing deterioration of the heater, as well as improving the uniformity of film thickness distribution by suppressing a reaction between the heater, substrate surface and gas components remaining after the processing.

### Means to Solve the Problems

Typical aspects of the present invention to solve the above mentioned problems are described as follows.

(1) A semiconductor device manufacturing method comprising the steps of:

loading a substrate into a processing chamber,

mounting the substrate on a support tool in the processing chamber,

processing the substrate mounted on the support tool by supplying process gas into the processing chamber,

purging the interior of the processing chamber after the substrate processing step, and

unloading the processed substrate from the processing chamber after the step of purging the interior of the processing chamber, wherein

in the step of purging the interior of the processing chamber, exhaust is performed toward above the substrate and toward below the substrate in the processing chamber, and the exhaust rate toward above the substrate is set larger than the exhaust rate toward below the substrate.

(2) A substrate processing apparatus comprising:

a processing chamber for processing a substrate,

a support tool for supporting the substrate in the processing chamber,

an elevator mechanism for raising and lowering the support tool,

a process gas supply system for supplying process gas into the processing chamber,

a purge gas supply system for supplying purge gas into the processing chamber,

a first exhaust port formed higher than an upper side of the support tool in a state where the support tool is lowered for exhausting the interior of the processing chamber,

a second exhaust port formed lower than an upper side of the support tool in a state where the support tool is lowered for exhausting the interior of the processing chamber, and

a controller for controlling to purge the interior of the processing chamber in a state where the support tool is lowering and/or a state where the support tool is lowered, and to make the exhaust rate from the first exhaust port larger than the exhaust rate from the second exhaust port during purging.

### Effect of Invention

The present invention according to the first (1) aspect is capable of improving the uniformity of film thickness distribution within the substrate surface by reducing the effect on the substrate of gas flow in a direction parallel (horizontal) to the substrate surface in order to suppress a reaction between the substrate surface and residual gas components in the purge step.

### BRIEF DESCRIPTION OF DRAWINGS

FIG. 1 is a plan cross sectional view showing the multi-chamber CVD apparatus of an embodiment of this invention;

FIG. 2 is a side cross sectional view of that multi-chamber CVD apparatus;

FIG. 3 is a front view including a circuit diagram showing the single-wafer CVD apparatus of an embodiment of this invention;

FIG. 4 is a fragmentary abbreviated frontal cross sectional view of the single-wafer CVD apparatus of an embodiment of this invention;

FIG. 5 is a fragmentary abbreviated and partially sectional front view showing the processing step by the single-wafer CVD apparatus of an embodiment of this invention;

FIG. 6A is a frontal cross sectional view of an essential section after lowering of the rotation drum of the single-wafer CVD apparatus of an embodiment of this invention, and shows the initial stage of the purge step;

FIG. 6B is a frontal cross sectional view of an essential section after lowering of the rotation drum of the single-wafer CVD apparatus of an embodiment of this invention, and shows the intermediate stage of the purge step;

FIG. 6C is a frontal cross sectional view of an essential section after lowering of the rotation drum of the single-wafer CVD apparatus of an embodiment of this invention, and shows the final stage of the purge step.

FIG. 7 is an illustrated view showing the exhausting of the single-wafer CVD apparatus of the comparative example;

FIG. 8A, FIG. 8B and FIG. 8C show the film thickness distribution when forming an amorphous silicon film on a wafer utilizing the single-wafer CVD apparatus of the comparative example;

FIG. 8A is a table showing the film thickness and film thickness uniformity;

FIG. 8B is a line graph showing the film thickness versus radius;

FIG. 8C is a two-dimensional map of the film thickness distribution;

FIG. 9A, FIG. 9B and FIG. 9C show the film thickness distribution when forming an amorphous silicon film on a wafer utilizing the single-wafer CVD apparatus of an embodiment of this invention;

FIG. 9A is a table showing the film thickness and film thickness uniformity;

FIG. 9B is a line graph showing the film thickness versus radius;

FIG. 9C is a two-dimensional map of the film thickness distribution;

FIG. 10 is a flow chart showing the sequence of the purge step in the single-wafer CVD apparatus of an embodiment of this invention.

### BEST MODE FOR CARRYING OUT THE INVENTION

An embodiment of the present invention is described next while referring to the drawings.

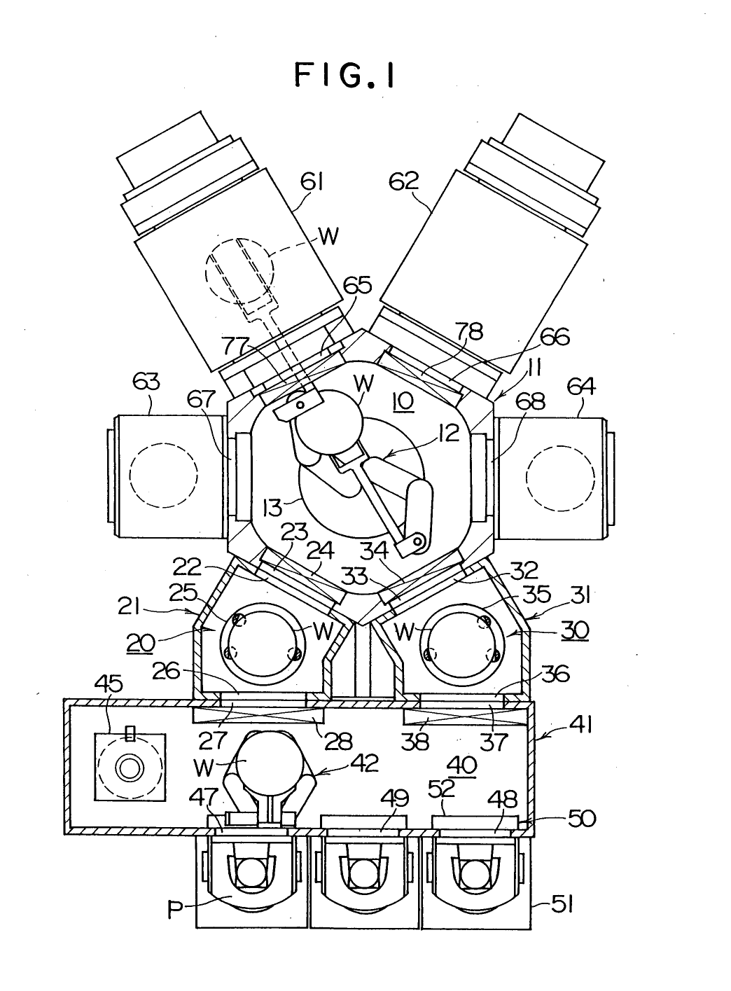

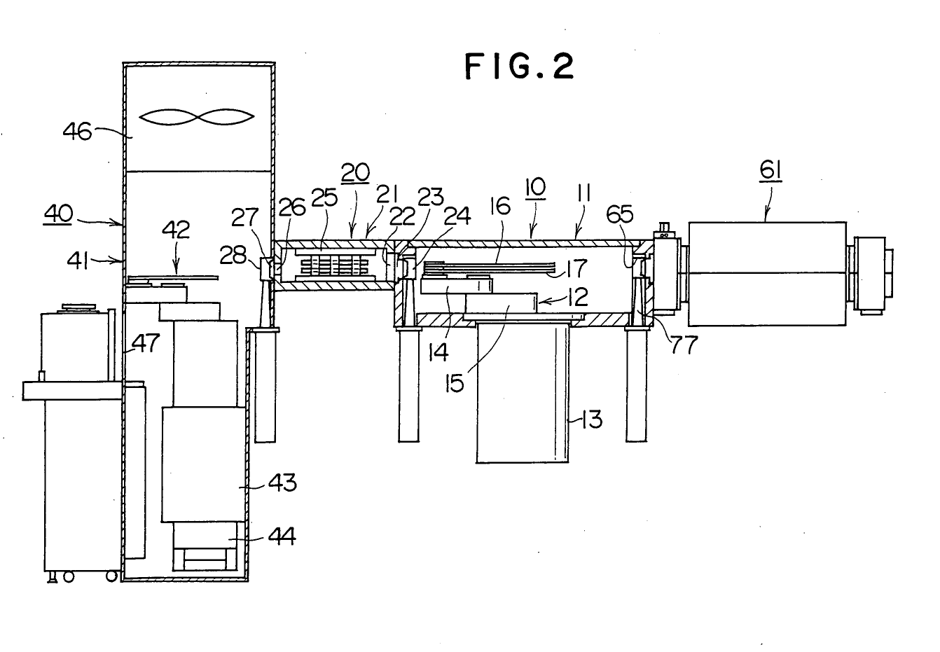

In this embodiment, as shown in FIG. 1 and FIG. 2, the substrate processing apparatus of the present invention is made up of a multi-chamber CVD apparatus (hereinafter called “CVD apparatus”). The CVD apparatus is used in a process for forming film by depositing a desired thin film on the wafer in the IC manufacturing method.

The CVD apparatus in this embodiment utilizes a FOUP (front opening unified pod, hereinafter called “pod”) that serves as the carrier for transporting the wafers.

In the following description, the front/rear/left/right directions are based on FIG. 1. Namely, a wafer transfer chamber 40 is on the front side, on the opposite side a wafer transfer chamber 10 is at the rear side, a carry-in pre-chamber 20 is at the left side, and a carry-out pre-chamber 30 is at the right side.

The CVD apparatus shown in FIG. 1 and FIG. 2 includes a first wafer transfer chamber (hereinafter, called “negative pressure transfer chamber”) 10 with a load-lock chamber structure for withstanding pressure (negative pressure) below atmospheric pressure. A case (hereinafter called “negative pressure transfer chamber case”) 11 of the negative pressure transfer chamber 10 is formed in a heptagonal shape as seen from a plan view and has a box-like shape sealed at the top and bottom ends.

A wafer transfer device (hereinafter called “negative pressure transfer device”) 12 for transferring the wafer W under negative pressure is installed in the center section of the negative pressure transfer chamber 10. This negative pressure transfer device 12 is made up of a SCARA robot (SCARA: selective compliance assembly robot arm). An elevator 13 installed in a bottom wall of the negative pressure transfer chamber case 11 raises and lowers the negative pressure transfer device 12 while sealed in an airtight state.

The negative pressure transfer device 12 contains a first arm (hereinafter called “upper arm”) 14 positioned on the upper side, and a second arm (hereinafter called “lower arm”) 15 positioned on the lower side.

An upper end effector 16 and a lower end effector 17 are each attached to the tip of the lower arm 15 and the upper arm 14. The upper end effector 16 and the lower end effector 17 are each formed in a fork shape with two branches to support the wafer W from the bottom.

A carry-in pre-chamber (hereinafter called “carry-in chamber”) 20 and a carry-out pre-chamber (hereinafter called “carry-out chamber”) 30 respectively adjoin and connect to two side walls positioned on the front side among the six side walls of the negative pressure transfer chamber case 11.

A case (hereinafter called “carry-in chamber case”) 21 for the carry-in chamber 20 and a case (hereinafter called “carry-out chamber case”) 31 for the carry-out chamber 30 are respectively formed in a generally rectangular shape as seen from a plan view and has a box-like shape sealed at the top and bottom ends. These cases 21, 31 has a load-lock chamber structure for withstanding negative pressure.

Carry-in ports 22, 23 are respectively formed on the mutually adjacent side walls of the negative pressure transfer chamber case 11 and the carry-in chamber case 21. A gate valve 24 for opening and closing the carry-in ports 22, 23 is installed on the carry-in port 23 on the side of the negative pressure transfer chamber 10.

A carry-in chamber temporary mounting stand 25 is installed in the carry-in chamber 20.

Carry-out ports 32, 33 are respectively formed on the mutually adjacent side walls of the negative pressure transfer chamber case 11 and the carry-out chamber case 31. A gate valve 34 for opening and closing the carry-out ports 32, 33 is installed on the carry-out port 33 on the side of the negative pressure transfer chamber 10.

A carry-out chamber temporary mounting stand 35 is installed in the carry-out chamber 30.

A second wafer transfer chamber (hereinafter called “positive pressure transfer chamber”) 40 capable of maintaining atmospheric pressure or higher (positive pressure), adjoins and connects to the front side of the carry-in chamber 20 and the carry-out chamber 30. A case (hereinafter called “positive pressure transfer chamber case”) 41 for the positive pressure transfer chamber 40 is a rectangular shape along the lateral length as seen from a plan view and forms a box-like shape sealed at the top and bottom ends.

A second wafer transfer device (hereinafter called “positive pressure transfer device”) 42 for transferring the wafer W under a positive pressure is installed in the positive pressure transfer chamber 40. This positive pressure transfer device 42 is made up of a SCARA robot structured to simultaneously transport two wafers.

An elevator 43 installed in the positive pressure transfer chamber 40 raises and lowers the positive pressure transfer device 42. A linear actuator 44 moves the positive pressure transfer device 42 back and forth in the left and right directions.

Carry-in ports 26, 27 are respectively formed on the mutually adjacent side walls of the carry-in chamber case 21 and the positive pressure transfer chamber case 41. A gate valve 28 for opening and closing these carry-in ports 26, 27 is installed on the carry-in port 27 on the side of the positive pressure transfer chamber 40.

Carry-out ports 36, 37 are respectively formed on the mutually adjacent side walls of the positive pressure transfer chamber case 41 and the carry-out chamber case 31. A gate valve 38 for opening and closing these carry-out ports 36, 37 is installed on the carry-out port 37 on the side of the positive pressure transfer chamber 40.

A notch aligner device 45 is installed on the left side of the positive pressure transfer chamber 40 as shown in FIG. 1.

A cleaning unit 46 for supplying clean air is installed on the positive pressure transfer chamber 40 as shown in FIG. 2.

Three wafer carry-in/out ports 47, 48, 49 are formed arrayed to the left and right on the front wall of the positive pressure transfer chamber case 41 as shown in FIG. 1 and FIG. 2. These wafer carry-in/out ports 47, 48, 49 are set to allow carrying the wafer W in and out of the positive pressure transfer chamber 40. Pod openers 50 are installed in each of these wafer carry-in/out ports 47, 48, 49.

The pod opener 50 contains a mounting stand 51 for loading the pod P, and a cap fitter/remover 52 for fitting and removing the cap on the pod P loaded on the mounting stand 51. The pod opener 50 is structured to open and close the wafer loading/unloading port of the pod P via the cap fitter/remover 52 for fitting or removing the cap on the pod P loaded on the mounting stand 51.

An internal process transfer device (RGV) not shown in the drawing, supplies the pod P to the mounting stand 51 of the pod opener 50 and ejects it. The mounting stand 51 is therefore configured as a pod stage serving as the carrier stage.

A first CVD unit 61 as a first processing unit, and a second CVD unit 62 as a second processing unit are respectively connected by way of gate valves 77, 78 to two side walls positioned on the rear side among the six side walls of the negative pressure transfer chamber case 11 as shown in FIG. 1. The first CVD unit 61 and the second CVD unit 62 are each single-wafer CVD apparatus (single-wafer type cold wall CVD apparatus).

Also, a first cooling unit 63 as a third processing unit, and a second cooling unit 64 as a fourth processing unit are respectively connected to the two mutually opposite side walls remaining among the six side walls of the negative pressure transfer chamber case 11. The first cooling unit 63 and the second cooling unit 64 are each structured so as to cool the processed wafer W.

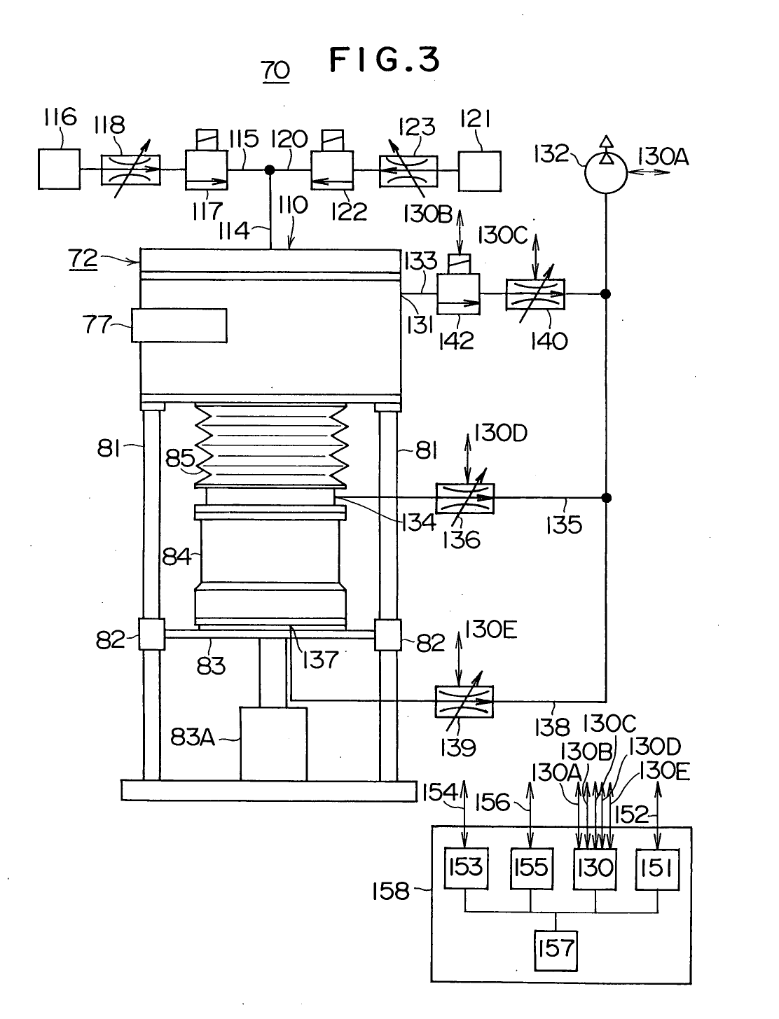

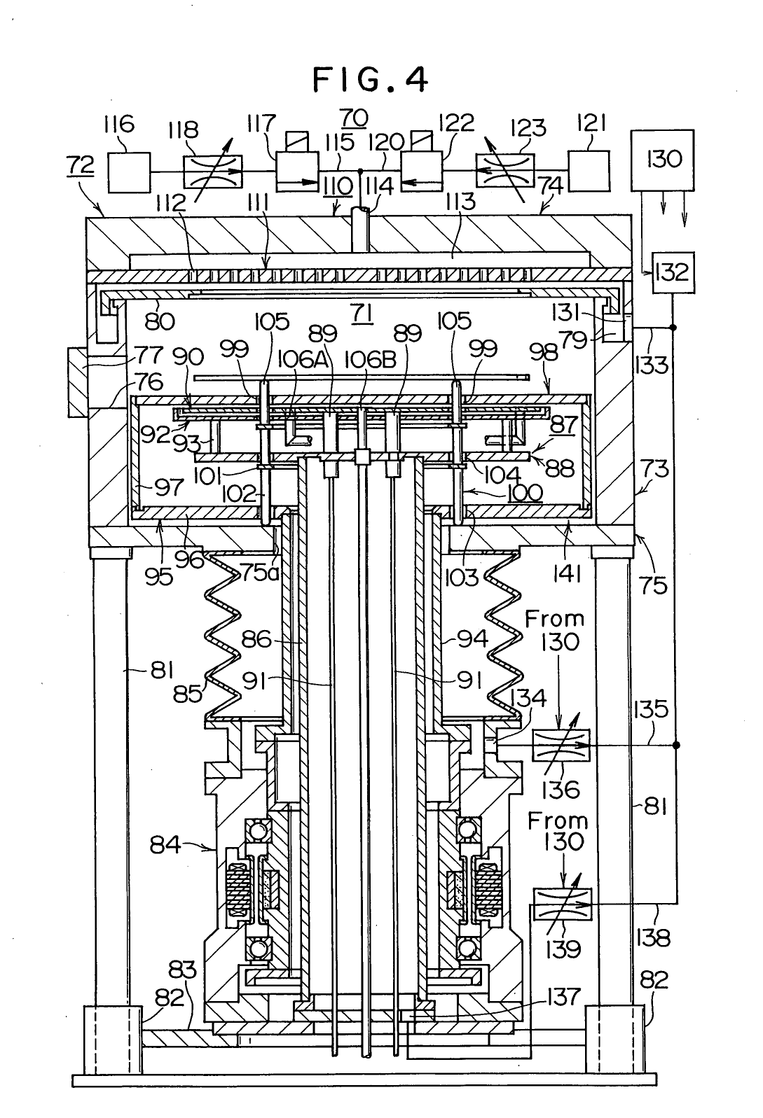

In the present embodiment, the single-wafer CVD apparatus 70 used for the first CVD unit 61 and the second CVD unit 62 is structured as shown in FIG. 3 and FIG. 4.

The single-wafer CVD apparatus 70 contains a case 72 forming a processing chamber 71 for processing the wafer W. A lower cup 73 and an upper cup 74 and a bottom cap 75 are assembled into the case 72. The case 72 is formed in a tubular shape sealed at the top and bottom ends.

A wafer load/unloading port 76 opened and closed by a gate valve 77 is formed with the lateral length in the horizontal direction in the middle section on the tubular wall of the lower cup 73 on the case 72. The wafer load/unloading port 76 is structured to allow the negative pressure transfer device 12 to carry-in and carry-out the wafer W to and from the processing chamber 71. In other words, as shown in FIG. 1, the wafer W is carried in and carried out to and from the processing chamber 71 through the wafer load/unloading port 76 in a state where supported mechanically from below by the end effector 16 of the negative pressure transfer device 12.

An exhaust buffer space 79 is formed in a ring shape on the top end of the upper cup 74. A cover plate 80 formed in a circular ring shape covers the top of the exhaust buffer space 79. The inner circumferential edge of the cover plate 80 is structured so as to cover the outer circumferential edge section of the wafer W.

Multiple support rods 81 horizontally support the case 72 as shown in FIG. 3. Also, elevator blocks 82 are respectively inserted into each of the support rods 81 for free upward and downward movement. An elevator stand 83 is horizontally provided between these elevator blocks 82.

An elevator drive device 83A utilizing air cylinder devices is structured to raise and lower the elevator stand 83.

A susceptor rotation device 84 is installed above the elevator stand 83. A bellows 85 is installed between the susceptor rotation device 84 and the case 72 to seal the internal space hermetically. The susceptor rotation device 84 utilizes a brushless DC motor. An output shaft (motor shaft) for the susceptor rotation device 84 is formed in a hollow shaft and structured to rotatably drive a rotating shaft 94 described later.

The elevator drive device 83A and the susceptor rotation device 84 are connected by an electrical cable 152 to a drive controller 151 shown in FIG. 3, and are controlled by the drive controller 151.

Circular insertion hole 75a is formed in the center of the bottom cap 75 of the case 72 as shown in FIG. 4. Support shaft 86 formed in a cylindrical shape is inserted in the insertion hole 75a and from below concentrically into the processing chamber 71. This support shaft 86 is raised and lowered while supported on the elevator stand 83.

A heating unit 87 is installed concentrically and affixed horizontally at the upper end of the support shaft 86. The heating unit 87 is raised and lowered by the support shaft 86. The heating unit 87 includes a support plate 88 formed in a circular plate shape. The upper end opening of the tubular support shaft 86 is clamped in the center section of the support plate 88.

Multiple electrodes 89 also serving as support shafts are installed at multiple locations and erected perpendicularly at the upper surface of the support plate 88. A heater 90 formed in a disk shape is clamped overhead at the top end of these electrodes 89. Electrical power cables 91 for supplying electrical power to the heater 90 are respectively connected to each electrode 89.

A reflector plate 92 installed horizontally on the lower side of the heater 90 in the heating unit 87 is supported by a support shaft 93 erected on the support plate 88. The reflector plate 92 is a thin film made from titanium and polished to a mirror finish. The reflector plate 92 is structured to effectively reflect perpendicularly upwards the heat rays radiating from the heater 90.

A rotating shaft 94 formed in a cylindrical shape with a diameter larger than the support shaft 86, is inserted from below concentrically into the processing chamber 71, on the outer side of the support shaft 86 in the insertion hole 75a of the bottom cap 75. The susceptor rotation device 84 installed on the elevator stand 83 is structured to rotate the rotating shaft 94. The rotating shaft 94 rises and lowers along with the support shaft 86 while supported on the elevator stand 83 via the susceptor rotation device 84.

A rotating drum 95 is installed concentrically and affixed horizontally at the upper end of the rotating shaft 94. The rotating shaft 94 rotates the rotating drum 95. In other words, the rotating drum 95 includes a rotating plate 96 formed in a flat donut shape, and a rotating tube 97 formed in a tubular shape. The inner periphery of the rotating plate 96 is affixed to the top end opening of the tubular rotating shaft 94. The rotating tube 97 is affixed concentrically to the outer circumferential periphery of the top surface of the rotating plate 96.

A susceptor 98 at the top end of the rotating tube 97 of the rotating drum 95, covers the top end opening of the rotating tube 97 as shown in FIG. 4. A heat-resistant material such as silicon carbide or aluminum nitride is utilized in the susceptor 98. The susceptor 98 is formed in a large disk shape with an outer diameter larger than the wafer W.

Three insertion holes 99 are formed perpendicularly at equally spaced intervals along the periphery, along identical radial circular lines near the periphery of the susceptor 98 shown in FIG. 4. The inner diameter of each insertion hole 99 is set to allow insertion of the pushup pins described later on.

A wafer elevator device 100 is installed on the rotating drum 95. The wafer elevator unit 100 is structured to push up the wafer W perpendicularly from below the susceptor 98 to make the wafer W rise from the upper surface of the susceptor 98. The wafer elevator device 100 contains an elevator ring 101 formed in a circular ring shape. The elevator ring 101 is installed concentrically with the support shaft 86 on the rotating plate 96 of the rotating drum 95.

Multiple (in this embodiment, three pins) pushup pins (hereinafter called “rotation side pins”) 102 on the lower side of the elevator ring (hereinafter called “rotation side ring”) 101 are installed pointing downward at equally spaced intervals along the periphery. Each rotation side pin 102 is installed on the rotation plate 96 along the same concentric line as the rotating shaft 94, and is respectively inserted for free sliding movement in each perpendicularly formed guide hole 103.

The length of each rotation side pin 102 is set to allow pushing up the rotation side ring 101 horizontally, and also set to match the extent of upward pushup of the susceptor 98 for the wafer W. The bottom edge of each rotation side pin 102 seats with and separates freely from the opposing bottom end of the processing chamber 71 or in other words, the top side of the bottom cap 75.

Multiple (in this embodiment, three holes) guide holes 104 are formed perpendicularly at equidistant intervals along the periphery on the support plate 88 of the heating unit 87. Each pushup pin 105 fits freely for sliding movement into each guide hole 104.

The bottom edge of each pushup pin 105 possesses an appropriate air gap on the upper edge of the rotation side ring 101. The pushup pins 105 therefore do not interfere with the rotation side ring 101 during rotation of the rotating drum 95.

The upper edge of the pushup pin 105 inserts through the reflector plate 92 and the heater 90 and faces the insertion hole 99 of the susceptor 98. The length of each pushup pin 105 is set to allow pushing up the wafer W horizontally, and also set to allow the upper end of the pushup pin 105 to face the bottom side of the susceptor 98 with an appropriate air gap in the state where seated on the support plate 98. In other words, the pushup pins 105 do not interfere with the susceptor 98 during rotation of the rotating drum 95.

A center radiation thermometer 106A and a middle radiation thermometer 106B and an outer radiation thermometer 106C are respectively installed as a temperature measurement means at positions facing the center, intermediate section and peripheral section in the bottom side of the susceptor 98. These radiation thermometers 106A, 106B and 106C each contain a waveguide rod for guiding heat rays from the susceptor 98 to the temperature sensor section (not shown in drawing).

The waveguide rod is made of quartz rod or optical fiber formed in a long, narrow rod shape. The center radiation thermometer 106A is formed in a straight line shape, but the middle radiation thermometer 106B and the outer radiation thermometer 1060 are each bent in a crank shape at the top end. The center radiation thermometer 106A, middle radiation thermometer 106B, and outer radiation thermometer 106C are respectively positioned so as not to interfere with the electrode 89, the electrical power cables 91, and the pushup pins, etc. The perpendicular section on the center radiation thermometer 106A, middle radiation thermometer 106B and outer radiation thermometer 106C are installed facing perpendicularly downward along the inner circumferential surface in the hollow section of the support shaft 86. These sections are inserted into the seal cap that sealed the bottom end opening of the support shaft 86 at the bottom end of the support shaft 86 and each is lead outwards.

Though not shown in the drawing, the end leadings of the waveguide rods of the center radiation thermometer 106A, middle radiation thermometer 106B, and outer radiation thermometer 106C from the hollow section of the support shaft 86 face the respective temperature sensor units on the center radiation thermometer 106A, middle radiation thermometer 106B, and outer radiation thermometer 106C.

The center radiation thermometer 106A, middle radiation thermometer 106B, and outer radiation thermometer 106C each connect via electrical wires 154 to a temperature controller 153 shown in FIG. 3. The center radiation thermometer 106A, middle radiation thermometer 106B, and outer radiation thermometer 106C each send the temperature measured at the sensor units to the temperature controller 153.

Incidentally, the electrical power cable 91 of the heater 90 also connects to the temperature controller 153 by way of the hollow section inside the support shaft 86. This temperature controller 153 performs sequence control and feedback control of the power supply.

As shown in FIG. 4, a gas head 110 is integrated into the upper cup 74 of the case 72 as a gas feed means.

The gas head 110 includes a disk-shaped shower plate 111 held between the surfaces of the upper cup 74 and the lower cup 73. Multiple shower ports 112 are formed uniformly across the entire surface of the shower plate 111 to allow communication of the upper and lower spaces.

The shower plate 111 is supported horizontally at intervals from the cover plate 80. The internal space formed by the upper surface of the shower plate 111 and the lower and inner circumferential surfaces of the upper cup 74 forms a gas accumulator 113.

The downstream side end of a gas feed pipe 114 is inserted so as to connect to the gas accumulator 113 at a point facing the center of the shower plate 111 of the upper cup 74. The gas accumulator 113 diffuses uniformly process gas fed to the gas feed pipe 114 and blows it uniformly as a shower from each shower port 112.

The gas feed pipe 114 as shown in FIG. 3 and FIG. 4, is connected to a process gas supply pipe 115 serving as the process gas supply system for supplying process gas within the processing chamber 71; and a purge gas supply pipe 120 as a purge gas system for supplying purge gas within the processing chamber 71.

The upstream end of the process gas supply pipe 115 connects to a process gas supply source 116. A stop valve 117 and a flow rate controller (mass flow controller) 118 as a flow rate control unit are installed on the way of the process gas supply pipe 115.

The process gas supply source 116 and the stop valve 117 and the flow rate controller 118 are connected to a gas supply controller 155 by way of an electrical wire 156 as shown in FIG. 3, and are regulated by the gas supply controller 155.

A purge gas supply source 121 is connected to the upstream end of the purge gas supply pipe 120. A stop valve 122 and a flow rate controller (mass flow controller) 123 as a flow rate control unit are installed on the way of the purge gas supply pipe 120.

The purge gas supply source 121 and the stop valve 122 and the flow rate controller 123 are regulated by the gas supply controller 155.

As shown in FIG. 4, a main exhaust port 131 serving as the first exhaust port for exhausting the inside of the process chamber 71 and formed to connect to the exhaust buffer space 79, is provided on a side wall facing the wafer load/unloading port 76 at the top end of the lower cup 73, at a position higher than the upper side of the susceptor 98 while the susceptor 98 has been lowered.

The main exhaust port 131 as shown in FIG. 3, is connected by way of a main exhaust pipe 133 to a vacuum exhaust device 132 made up of a vacuum pump, etc. A main exhaust valve 142 made up of an open/close valve and an APC (Auto Pressure Control) valve 140 as a pressure regulator unit, are installed on the way of the main exhaust pipe 133.

The main exhaust valve 142 and the APC valve 140 are omitted from the drawing of FIG. 4 for the sake of convenience.

As shown in FIG. 4, a side exhaust port 134 serving as the second exhaust port for exhausting the interior of a processing chamber side space 141 occurring between the rotating plate 96 and the bottom cap 75 due to raising and lowering of the rotating drum 95, is provided on the side wall of the susceptor rotation device 84 below the bellows 85. This side exhaust port 134 is formed so as to connect to the processing chamber side space 141 and the processing chamber 71 via the insertion holes 75a of the bottom cap 75 and the hollow section of the bellows 85.

The side exhaust port 134 is provided lower than the susceptor 98 while the susceptor 98 is in a lowered state. However, the side exhaust port 134 may be provided on the side of the susceptor 98 while the susceptor 98 is in a lowered state, or in other words on the side wall of the lower cup 73.

The side exhaust port 134 is connected by way of the side exhaust pipe 135 to the vacuum exhaust device 132 as shown in FIG. 3. A side exhaust valve 136 is installed on the way of the side exhaust pipe 135.

The side exhaust valve 136 is made up of a flow rate adjuster valve to adjust the flow rate of the needle valve, etc. The side exhaust valve 136 is structured to adjust the exhaust flow quantity from the side exhaust port 134.

A chuck exhaust port 137 serving as the third exhaust port for exhausting the interior of the rotating drum 95 and the support shaft 86 is provided on the bottom wall of the support shaft 86. The chuck exhaust port 137 connects to the processing chamber 71 by way of the multiple insertion holes 99 of the susceptor 98 and the hollow section of the rotating drum 95 and the hollow section of the support shaft 86.

The chuck exhaust port 137 connects by way of a chuck exhaust pipe 138 to the vacuum exhaust device 132 as shown in FIG. 3. A chuck exhaust valve 139 is installed on the way of the chuck exhaust pipe 138.

The chuck exhaust valve 139 is made up of a flow rate adjuster valve to adjust the flow rate of the needle valve, etc. The chuck exhaust valve 139 is structured to adjust the exhaust flow quantity from the chuck exhaust port 137.

As shown in FIG. 3, the vacuum exhaust device 132, the main exhaust valve 142, the APC valve 140, the side exhaust valve 136, and the chuck exhaust valve 139 are each connected to the exhaust controller 130 respectively by an electrical wire 130A, 130B, 130C, 130D, and 130E, and are regulated by the exhaust controller 130.

The exhaust controller 130 is structured so as to perform exhaust as described later.

During exhaust of the interior of the processing chamber 71 in a state where the susceptor 98 is lowering or when the susceptor 98 is lowered, the exhaust controller 130 is structured to execute control so that the exhaust quantity from the main exhaust port 131 is larger than the exhaust quantity from the side exhaust port 134, and also so that it is equivalent to or larger than the exhaust quantity from the chuck exhaust port 137.

As shown in FIG. 3, the exhaust controller 130, the drive controller 151, the temperature controller 153, the gas supply controller 155 are connected to a main controller 157 for controlling the overall CVD apparatus, and are regulated by the main controller 157.

A controller 158 includes the exhaust controller 130, the driver controller 151, the temperature controller 153, the gas supply controller 155, and the main controller 157.

The film-forming process in the IC manufacturing method utilizing the CVD apparatus configured as related above is described next.

In the following description, the controller 158 controls the operation of each unit making up the CVD apparatus.

The overall flow of the wafer W in the film-forming process is described first.

The 25 wafers W for film-forming are stored in a pod P, and are sent by the process internal transfer device to the CVD apparatus for performing the film-forming process.

As shown in FIG. 1 and FIG. 2, the pod P that was transferred is placed on the mounting stand 51 of the pod opener 50 in the carry-in chamber 20 from the process internal transfer device. The cap fitter/remover 52 removes the cap of the pod P and opens the wafer load/unload port of the pod P.

When the pod opener 50 opens the pod P, the positive pressure transfer device 42 placed in the positive pressure transfer chamber 40, picks up one wafer W at a time from the pod P by way of the wafer carry-in/out port 47. The positive pressure transfer device 42 carries in the wafer to the carry-in chamber 20 by way of the carry-in ports 26, 27, and transfers the wafer W onto the carry-in chamber temporary mounting stand 25.

During this transfer operation, the gate valve 24 closes the carry-in ports 22, 23 on the negative pressure transfer chamber 10 side. The pressure in the negative pressure transfer chamber 10 is maintained for example at 100 Pa.

After completing transfer of the wafers W of the pod P to the carry-in chamber temporary mounting stand 25, the gate valve 28 closes the carry-in ports 26, 27 on the positive pressure transfer chamber 40 side, and the exhaust device (not shown in drawing) exhausts the carry-in chamber 20 to a negative pressure. The gate valve 24 opens the carry-in ports 22, 23 on the negative pressure transfer chamber 10 side, when the carry-in chamber 20 depressurizes to the preset pressure value.

Next, the negative pressure transfer device 12 of the negative pressure transfer chamber 10 picks up one wafer W at a time from the carry-in chamber temporary mounting stand 25 by way of the carry-in ports 22, 23 and carries it into the negative pressure transfer chamber 10.

After the gate valve 24 closes, the negative pressure transfer device 12 carries the wafer W that was carried into the negative pressure transfer chamber 10, via the wafer carry-in/out port 65 into the processing chamber 71 of the single-wafer CVD apparatus 70 serving as the first CVD unit 61.

During carry-in of the wafer W from the carry-in chamber 20 into the first CVD unit 61, the interior of the carry-in chamber 20 and the negative pressure transfer chamber 10 are vacuum-exhausted beforehand so that the oxygen and moisture are removed. In this way, oxygen and moisture from the outside are prevented from penetrating into the interior of the processing chamber 71 of the first CVD unit 61 while the wafer is being carried into the first CVD unit 61.

After the gate valve 77 closes, the single-wafer CVD apparatus 70 serving as the first CVD unit 61 forms a thin film on the wafer W by the CVD method described later.

Then when the specified film-forming process in the first CVD unit 61 is completed, the gate valve 77 opens, the negative pressure transfer device 12 picks up the now processed wafer W from the first CVD unit 61, and carries out the wafer from the wafer carry-in/out port 65 of the first CVD unit 61 to the negative pressure transfer chamber 10 maintained at a negative pressure.

When the now processed wafer W is carried out from the first CVD unit 61 to the negative pressure transfer chamber 10, the gate valve 77 closes and along with the negative pressure transfer device 12 carrying the wafer W by way of the wafer carry-in/out port 67 into the cooling chamber of the first cooling unit 63, transfers it to the wafer mounting stand of the cooling chamber. The first cooling unit 63 then cools the now processed wafer.

The operation of transferring the wafer W processed in the first CVD unit 61, from the first CVD unit 61 to the first cooling unit 63, is performed in the negative pressure transfer chamber 10, and the first cooling unit 63, and the first CVD unit 61 all maintained at a negative pressure. Therefore, a natural oxidized film is prevented from forming on the thin film formed on the surface of the wafer W and foreign objects are prevented from adhering to the wafer W in the operation of transferring the wafer W from the first CVD unit 61 to the first cooling unit 63.

When a preset cooling time elapses in the first cooling unit 63, the negative pressure transfer device 12 picks up the now cooled wafers W from the first cooling unit 63, and after it is transferred to the negative pressure transfer chamber 10 and the gate valve 34 is opened, it is carried out by way of the carry-out port 33 to the carry-out chamber 30 and transferred to the carry-out chamber temporary mounting stand 35.

The gate valve 34 then closes.

The above operation is repeated, and a specified number of wafers, for example 25 wafers W carried into the carry-in chamber 20 are sequentially processed.

After processing of all wafers W carried into the carry-in chamber 20 is completed, the processed wafers W are all stored in the carry-out chamber 30. When the gate valve 34 closes the carry-out chamber 30, the interior of the carry-out chamber 30 is returned to approximately atmospheric pressure by using inert gas.

The gate valve 38 opens when the carry-out chamber 30 returns to atmospheric pressure, and the pod opener 50 opens the cap of empty pod P placed on the mounting stand 51.

Next, the positive pressure transfer device 42 of the positive pressure transfer chamber 40 picks up the wafer W from the carry-out chamber temporary mounting stand 35 and carries it out via the carry-out port 37 to the positive pressure transfer chamber 40, and charges it in the pod P by way of the wafer carry-in/out port 48 of the positive pressure transfer chamber 40.

When finished storing the processed 25 wafers W into the pod P, the cap fitter/remover 52 of the pod opener 50 fits the cap of the pod P onto the wafer loading/unloading port of the pod P and the pod P is closed.

The internal process transfer device transports the closed pod P from the mounting stand 51 to the next process.

The above operation described using the first cooling unit 63 and the first CVD unit 61. However, the same operation is performed using the second cooling unit 64 and the second CVD unit 62.

The film-forming process in the IC manufacturing method of an embodiment of the present invention is described next for the case where using the single-wafer CVD apparatus 70.

In the wafer loading step of carrying the wafer W into the processing chamber 71 as shown in FIG. 4, the rotating shaft 94 and the support shaft 86 lower the rotating drum 95 and the heating unit 87 to the lower limit position, namely the wafer carry-in/out position. The bottom end of the rotating side pin 102 of the wafer elevator device 100, butts up against the bottom side of the processing chamber 71 or in other words, the upper surface of the bottom cap 75. The rotation side ring 101, rises relative to the rotating drum 95 and the heating unit 87.

The three push-up pins 105 insert through the insertion holes 99 from below the susceptor 98 in order for the raised rotation side ring 101 to raise up the pushup pins 105, and receive the wafer W in a raised state from the top side of the susceptor 98.

The pressure within the processing chamber 71 on the other hand is regulated to the same pressure (for example, 100 Pa) as the negative pressure transfer chamber 10.

When the gate valve 77 opens the wafer load/unloading port 76, the negative pressure transfer device 12 carries the wafer W received by the end effector 16 in the negative pressure transfer chamber 10, from the wafer load/unloading port 76 into the processing chamber 71.

At this time, the stop valve 122 of the purge gas supply pipe 120 opens, and the purge gas G2 whose flow is regulated by the flow rate controller 123, is supplied in a small amount for example 0.5 slm (standard liters per minute) to the gas feed pipe 114.

The end effector 16 transfers the wafer W so that the wafer center position above the susceptor 98 matches the center of the susceptor 98. When the wafer W is transferred to the specified position, the end effector 16 slightly lowers to transfer the wafer W onto the three pushup pins 105.

The end effector 16 that transferred the wafer W to the three pushup pins 105, retracts from the wafer load/unloading port 76 to outside the processing chamber 71.

When the end effector 16 retracts from the processing chamber 71, the gate valve 77 closes the wafer load/unloading port 76.

As can be seen by referring to FIG. 5, when the gate valve 77 is closed, the elevator drive device operation to raise the rotating shaft 94 and the support shaft 86, raises the rotating drum 95 and the heating unit 87 versus the processing chamber 71.

In the initial stage of raising the rotating drum 95, the rotation side pin 102 butts up against the bottom side of the processing chamber 71 or in other words, the upper side of the bottom cap 75 and, the pushup pins 105 are mounted on the rotation side ring 101. The wafer W supported on the three pushup pins 105 therefore lowers relatively steadily versus the rotating drum 95 as the rotating drum 95 rises.

When the rotating drum 95 rises to the specified height, the pushup pins 105 are in a state where drawn into the lower part of the insertion holes 99 of the susceptor 98 so that the wafer W is mounted on the susceptor 98.

The rotating drum 95 rises further after the wafer W is mounted on the susceptor 98, and the upper side of the wafer W approaches the bottom surface of the shower plate 111, and when reaching the wafer processing position, the rise of the rotating drum 95 is stopped.

The chuck exhaust valve 139 opens when the rotating drum 95 is raised from the wafer carry-in/out position to the wafer processing position. The chuck exhaust valve 139 closes when the wafer W is mounted on the susceptor 98.

The chuck exhaust valve 139 remains closed until the interior has been sufficiently exhausted through the main exhaust port 131 and the side exhaust port 134 in the purge step after the film-forming.

The opening of the chuck exhaust valve 139 exhausts the interiors of the rotating drum 95 and the support shaft 86 via the chuck exhaust port 137 and the chuck exhaust pipe 138, so that the phenomenon of the wafer W rising above the susceptor 98 is prevented by the pressure differential between the hollow cavity in the rotating drum 95 and the processing chamber 71 drawn a vacuum through the main exhaust port 131.

The rotating shaft 94 rotates the rotating drum 95, in the processing step for supplying process gas into the processing chamber and processing the wafer W.

At this time, the rotation side pins 102 separate from the bottom side of the processing chamber 71, and the pushup pins 105 separate from the rotation side ring 101. The wafer elevator device 100 therefore does not interfere with the rotation of the rotating drum 95, and the heating unit 87 can be maintained in a stopped state.

In other words, in the wafer elevator device 100, the rotation side ring 101 rotates along with the rotating drum 95, and the pushup pins 105 are in a stopped state along with the heating unit 87.

The sequence controller for the temperature controller 153 utilizes the heater 90 to heat the wafer W mounted on the susceptor 98 to the target temperature uniformly across the entire surface. The radiation thermometers 106A, 106B and 106C measure the temperature of the susceptor 98 at this time. The temperature controller 153 performs feedback control to regulate the amount of heat from the heater 90 according to the measurement results from these radiation thermometers.

The vacuum exhaust device 132 on the other hand, exhausts the interior of the processing chamber 71 from the main exhaust valve 131 via the APC valve 140, and the exhaust controller 130 regulates the pressure inside the processing chamber 71 to reach a specified processing pressure (for example, 1,000 Pa to 50,000 Pa).

The stop valve 117 for the process gas supply pipe 115 opens when the rotation of the rotating drum 95 and the pressure within the processing chamber 71 and the wafer W temperature have stabilized as shown in FIG. 5, and process gas G1 is fed into the gas feed pipe 114.

The exhaust pressure from the main exhaust port 131 acts uniformly via the multiple shower ports 112 in the gas accumulator 113 so that after the process gas G1 from the gas feed pipe 114 flows into the gas accumulator 113, it diffuses radially outwards in the gas accumulator 113.

The exhaust pressure from the main exhaust port 131 acts uniformly on each shower port 112 so that the process gas G1 that diffused into the gas accumulator 113 is blown out uniformly from the multiple shower ports 112 in a shower across the entire surface of the wafer W.

After the process gas G1 that was blown out uniformly in a shower from the shower ports 112 has uniformly contacted the entire surface of the wafer W on the susceptor 98, the process gas G1 is suctioned into the main exhaust port 131 by way of the exhaust buffer space 79 and is exhausted.

The shower ports 112 at this time, blows out the process gas G1 uniformly in a shower, and the rotating drum 95 rotates the wafer W so that the process gas G1 makes uniform contact with the entire surface of the wafer W. Moreover, the heater 90 heats the wafer W to a uniform surface temperature distribution under feedback control from the temperature controller 153 so that the film thickness and the film quality distributions of the CVD film formed on the wafer W by the process gas G1 is uniform across the entire wafer W surface.

Processing conditions when forming amorphous silicon film using disilane gas are disilane gas flow rate of 0.005 to 0.1 slm, a processing temperature of 400 to 700° C., and a process pressure of 1,000 to 50,000 Pa.

Incidentally, the processing conditions when forming amorphous silicon film using monosilane gas are monosilane gas flow rate of 0.3 to 0.5 slm, a processing temperature of 500 to 800° C., and a process pressure of 1,000 to 50,000 Pa.

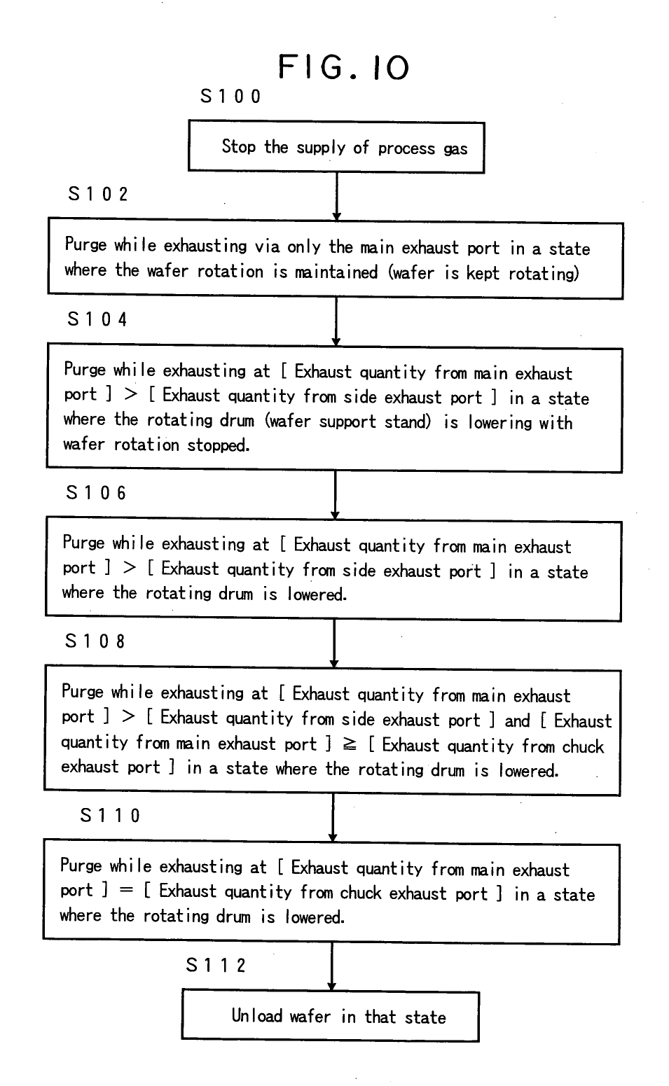

The purge step sequence is described next in detail while referring to FIG. 10.

In the initial stage of the purge step after the process time for the processing step has elapsed, the stop valve 117 for the process gas supply pipe 115 is closed and the supply of the process gas G1 is stopped (S100).

The susceptor rotation device 84 does not stop the rotation of the rotating drum 95 and that state is maintained. In other words, the interior of the processing chamber 71 is purged while rotating the wafer W in the initial stage of the purge step.

The stop valve 122 for the purge gas supply pipe 120 is opened and the purge gas G2 is supplied into the processing chamber 71 from the gas feed pipe 114.

The exhaust controller 130 on the other hand, controls the APC valve 140 and the vacuum exhaust device 132 to fix the exhaust flow rate from the main exhaust 131 (S102).

At this stage, when the APC valve 140 is fully opened, and the interior of the processing chamber 71 is drawn a vacuum by way of the main exhaust port 131 at a maximum exhaust flow rate (for example, 20 slm) from the vacuum exhaust device J32, the wafer W might spring upward for reasons related later. Therefore, the APC valve 140 is opened to a specified amount.

In this way, prior to lowering the wafer W after film-forming to the wafer carry-in/out position, or in other words during purging of the processing chamber 71 in a state where the wafer W is placed at the wafer processing position, by rotating the rotating drum 95 to rotate the wafer W and carrying out purging, even if residual gas components react with the wafer surface, the reaction is uniform across the entire wafer surface so that deterioration in film thickness uniformity on the wafer surface can be suppressed.

Next, the susceptor rotation device 84 stops the rotation of the rotating drum 95, and the exhaust controller 130 exerts control to open the side exhaust valve 136, and start exhausting from the space below the rotating drum 95 in the processing chamber 71 or in other words the side exhaust port 134 of the processing chamber side space 141.

The processing chamber side space 141 is at this time drawn a vacuum at a specified exhaust quantity (for example, 13 slm) by way of the side exhaust port 134.

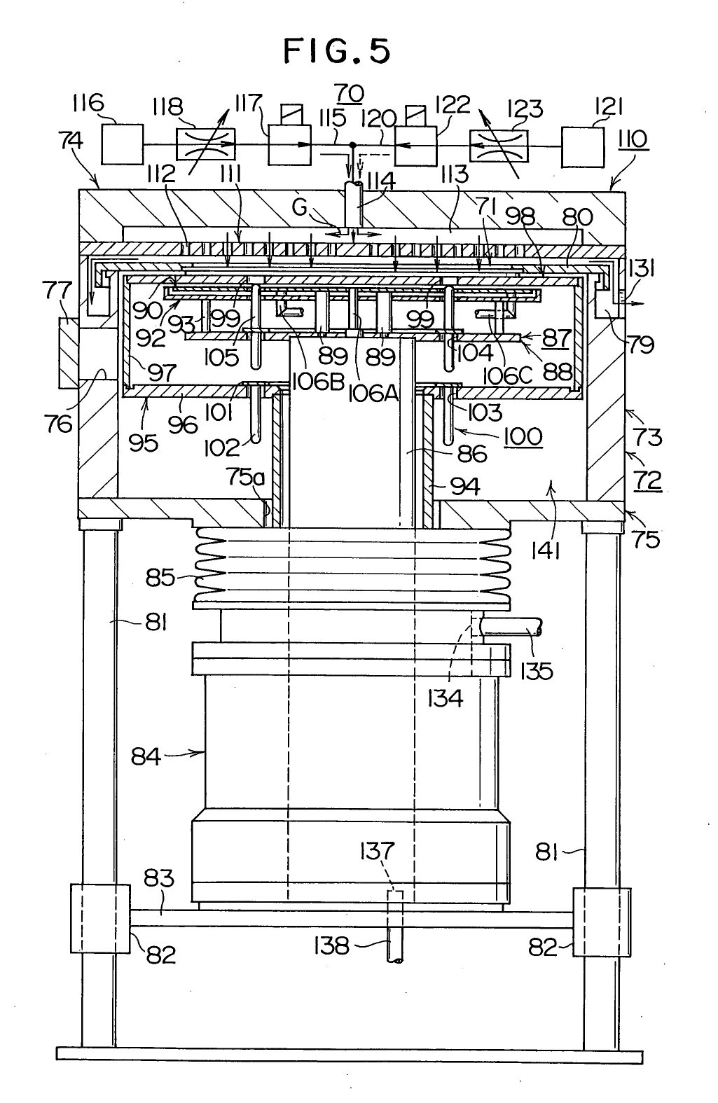

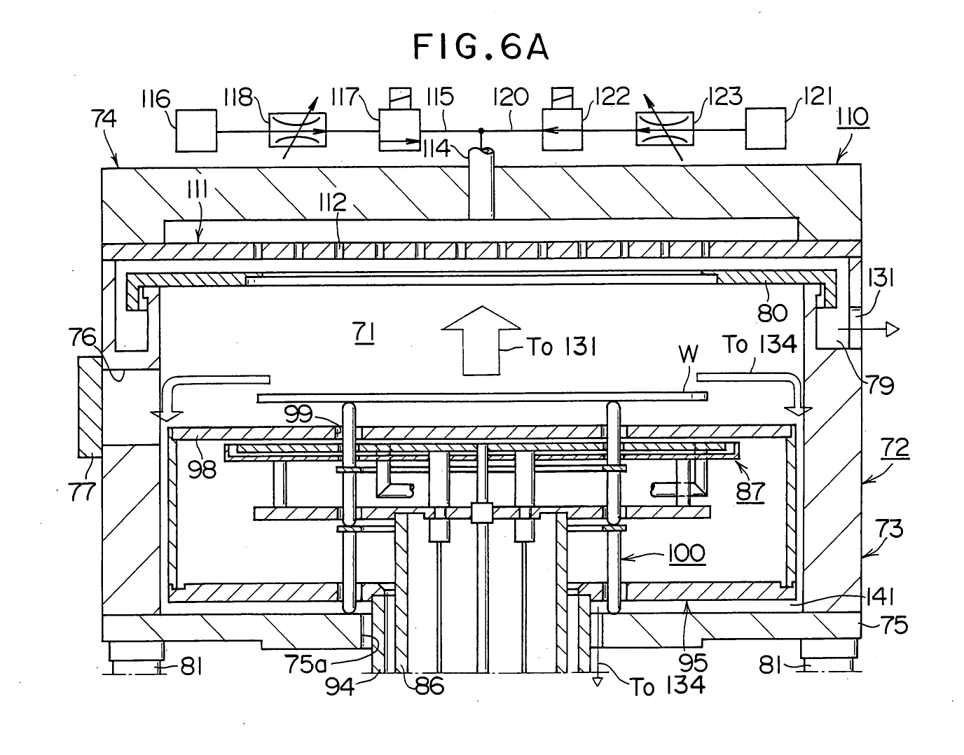

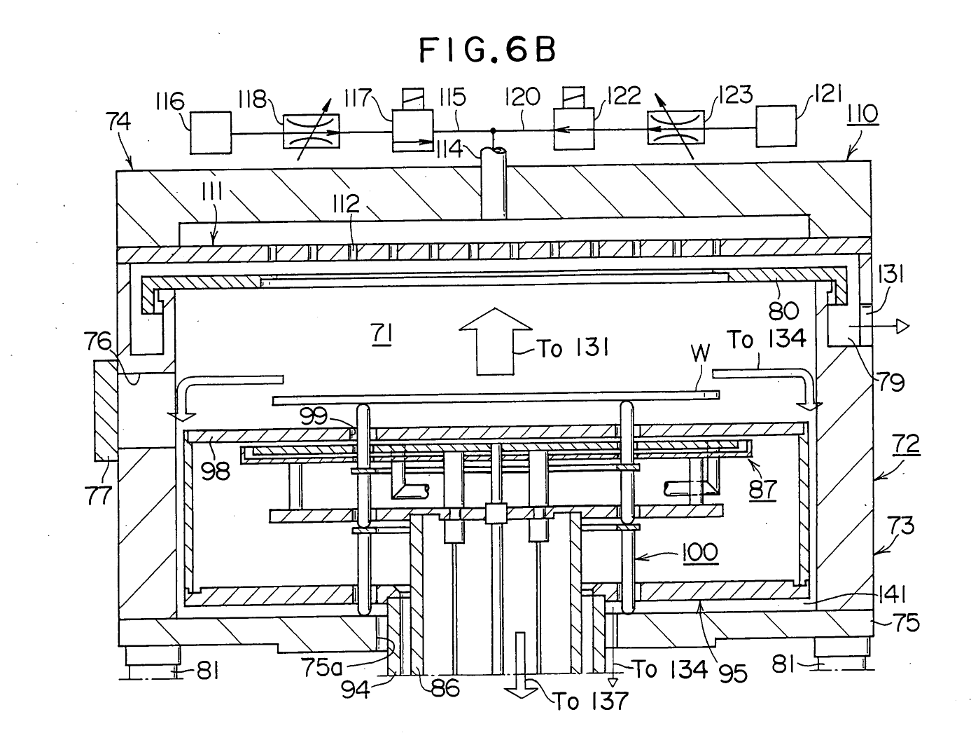

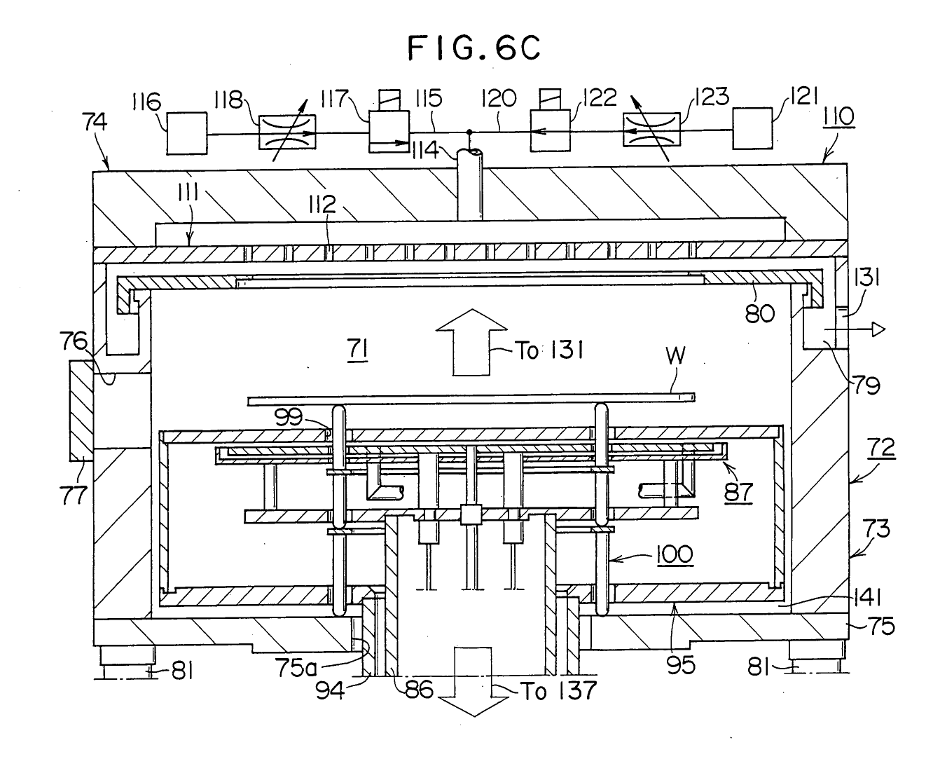

Next as shown in FIG. 6A, the elevator drive device lowers the rotating shaft 94 and the support shaft 86 to lower the rotating drum 95 and the heating unit 87.

The supply of purge gas G2 is maintained at this time, with the stop valve 122 of the purge gas supply pipe 120 still open. In other words, the purge gas G2 is supplied into the processing chamber 71 and exhausted from the main exhaust port 131 and the side exhaust port 134 when the rotating drum 95 and heating unit 87 are lowered.

Also at this time, the APC valve 140 is fully opened, and the interior of the processing chamber 71 is vacuum-exhausted from the main exhaust port 131 at maximum exhaust quantity (for example 20 slm) of the side exhaust port 134. The exhaust quantity from the main exhaust port 131 is set to a larger exhaust quantity than the side exhaust port 134 (S104).

However, during lowering of the rotating drum 95, the atmosphere in the space on the lower side of the rotating drum 95 within the processing chamber 71, is stirred up, namely by compression in the processing chamber side space 141, passes through the clearance between the inner circumference of the processing chamber 71 and the outer circumference of the rotating drum 95, and flows into the space on the upper side of the rotating drum 95. When this atmosphere stirred up from the lower space flows into the upper side space, it might cause adverse effects such as particles adhering to the wafer W.

However, while the rotating drum 95 is lowered, the space on the lower side of the rotating drum 95 within processing chamber 71 is exhausted by way of the side exhaust port 134 so that as the rotating drum 95 lowers, the atmosphere on the lower side space is prevented from flowing into the upper side space. Therefore, particles can be prevented beforehand from adhering to the wafer W.

The lower end on the rotation side pin 102 of the wafer elevator device 100 butts up against the bottom surface of the processing chamber 71, namely the upper side of the bottom cap 75 while the rotating drum 95 is lowering, so that the rotation side ring 101 rises relative to the rotating drum 95 and the heating unit 87.

The raised rotation side ring 101 raises the pushup pins 105 so that the three pushup pins 105 insert through the insertion holes 99 of the susceptor 98 from below, and makes the wafer W rise above the top side of the susceptor 98 while the wafer W is still maintained in a horizontal state.

When the wafer elevator device 100 has raised the wafer W above the top side of the susceptor 98, a space for inserting the end effector 16 is formed in the space below the wafer W, or in other words between the top side of the susceptor 98 and the lower side of the wafer W.

The purging continues even after the rotating drum 95 has lowered to the wafer carry-in/out position, the same as when lowering the rotation drum 95 (S106).

Then, after sufficiently purging the processing chamber 71, and in a state where purge gas G2 is supplied into the processing chamber 71 which is kept exhausted from the main exhaust port 131 and the side exhaust port 134 as shown in FIG. 6B, the chuck exhaust valve 139 opens, so that by adjusting the exhaust flow rate via chuck exhaust valve 139, the interiors of the rotating drum 95 and the support shaft 86 are drawn a vacuum at a preset specified exhaust flow rate (for example, 13 slm to 20 slm) from the chuck exhaust port 137.

At this time, the APC valve 140 is maintained in a fully open state, and the vacuum exhaust device 132 draws a vacuum in the interior of the processing chamber 71 at its maximum exhaust quantity (for example, 20 slm) from the main exhaust port 131.

The side exhaust valve 136 is also maintained in an open state, and the processing chamber side space 141 is also drawn a vacuum at a specified exhaust quantity (for example, 13 slm) from the side exhaust port 134.

The exhaust quantity from the main exhaust port 131 is set at this time to a larger exhaust quantity than the side exhaust port 134. Moreover, the exhaust flow quantity from the main exhaust port 131 is set to a larger exhaust quantity than the exhaust quantity from the chuck exhaust port 137, or the exhaust quantity from the main exhaust port 131 is set to an exhaust quantity equal to the chuck exhaust port 137 exhaust quantity (S108).

If the exhaust quantity from the main exhaust port 131 is the same as from the chuck exhaust port 137, then the chuck exhaust valve 139 is opened fully.

Then, in a state where purge gas G2 is supplied into the processing chamber 71 which is kept exhausted from the main exhaust port 131 and the chuck exhaust port 137 as shown in FIG. 6C, the exhaust controller 130 closes the side exhaust valve 136 and stops the exhausting from the side exhaust port 134.

The APC valve 140 is maintained in a fully open state at this time, the interior of the processing chamber 71 is drawn a vacuum at a maximum exhaust quantity from the main exhaust port 131, the chuck exhaust valve 139 is also fully opened, and the interiors of the rotating drum 95 and the support shaft 86 are drawn a vacuum at a maximum exhaust quantity from the chuck exhaust port 137. The main exhaust port 131 and the chuck exhaust port 137 are set to the same exhaust quantity at this time (S110). In this state, the interior of the processing chamber 71 is regulated to the same pressure as within the negative pressure transfer chamber 10.

In the unloading step for carrying the wafer W out from the processing chamber 71, the pressure in the processing chamber 71 is first regulated to the same amount of pressure as within the negative pressure transfer chamber 10, and the gate valve 77 opens the wafer load/unloading port 76.

Next, the end effector 16 of the negative pressure transfer device 12 is inserted from the wafer load/unloading port 76 into the insertion space formed between the wafer W and the susceptor 98. The end effector 16 inserted below the wafer W is then raised to receive the wafer W. After receiving the wafer W, the end effector 16 retracts from the wafer load/unloading port 76 and carries the wafer W out from the processing chamber 71 (S112).

By repeating the above related operations, the single-wafer CVD apparatus 70 performs processing to form the CVD film on the wafer W.

In the above purging step, purging while lowering the rotating drum 95 as in S104 or purging after lowering the rotating drum 95 as in S106, S108, S110 is carried out for the purpose of improving purge efficiency as well as suppressing effects from residual gas components.

In other words, when purging while lowering the rotating drum 95 or purging after lowering the rotating drum 95, the pushup pins 105 thrust the wafer W upward and purge is performed in a state where the insertion holes 99 of the susceptor 98 blocked by the wafer W are opened so that a pressure differential cannot easily occur between the interior of the processing chamber 71 and the interior of the rotating drum 95 even if the exhaust quantity from the main exhaust port 131 is increased, and therefore the wafer W is not prone to jump upward. Exhaust can therefore be performed for example with the main exhaust valve 142 fully open.

In contrast, when purging while the rotating drum 95 is placed in the wafer processing position, since purge is carried out in a state where the insertion holes 99 of the susceptor 98 are blocked by the wafer W, a pressure differential occurs between the interior of the processing chamber 71 and the interior of the rotating drum 95 when the exhaust quantity from the main exhaust port 131 is increased so that the wafer W jumps upward. Exhaust therefore cannot be performed with the main exhaust valve 142 fully open.

Thus, by purging, while lowering the rotation drum 95 or purging after the rotating drum 95 is lowered, the exhaust quantity from the main exhaust port 131 can be increased without the wafer W jumping upward, and purge efficiency can be improved even during exhaust with the main exhaust valve 142 fully open.

Moreover, lowering the rotating drum 95 makes the wafer W position farther from the main exhaust port 131, and the main exhaust port 131 is positioned above the wafer W so that exhaust can be performed toward above the wafer W via the main exhaust port 131. The quantity of exhaust flowing upward over the wafer W can be regulated to a quantity larger than the exhaust flow to below the wafer W, and the effect of residual gas components flowing laterally can be weakened.

Also, when purging while lowering the rotation drum 95 or purging after the rotating drum 95 is lowered, the gap between the wafer W and the ceiling surface of the processing chamber 71 is larger than during film-forming. In other words, purging can be performed in the larger space above the wafer W for gas flow than during film-forming, so that the lateral flow of gas can be weakened, and the wafer can be less susceptible to the effect of laterally flowing residual gas components.

However, the present inventors revealed that when using disilane gas to form amorphous silicon film on an area with little activation energy, the residual disilane gas components reacted with the wafer surface in the purge step causing a phenomenon where the film thickness distribution uniformity within the film surface affected the gas flow in the purge step.

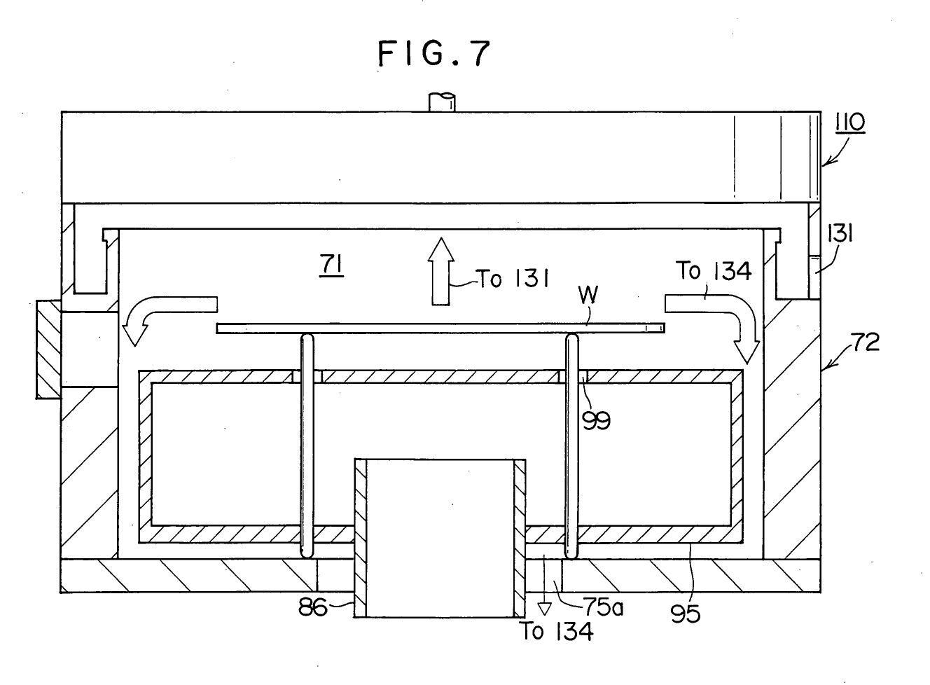

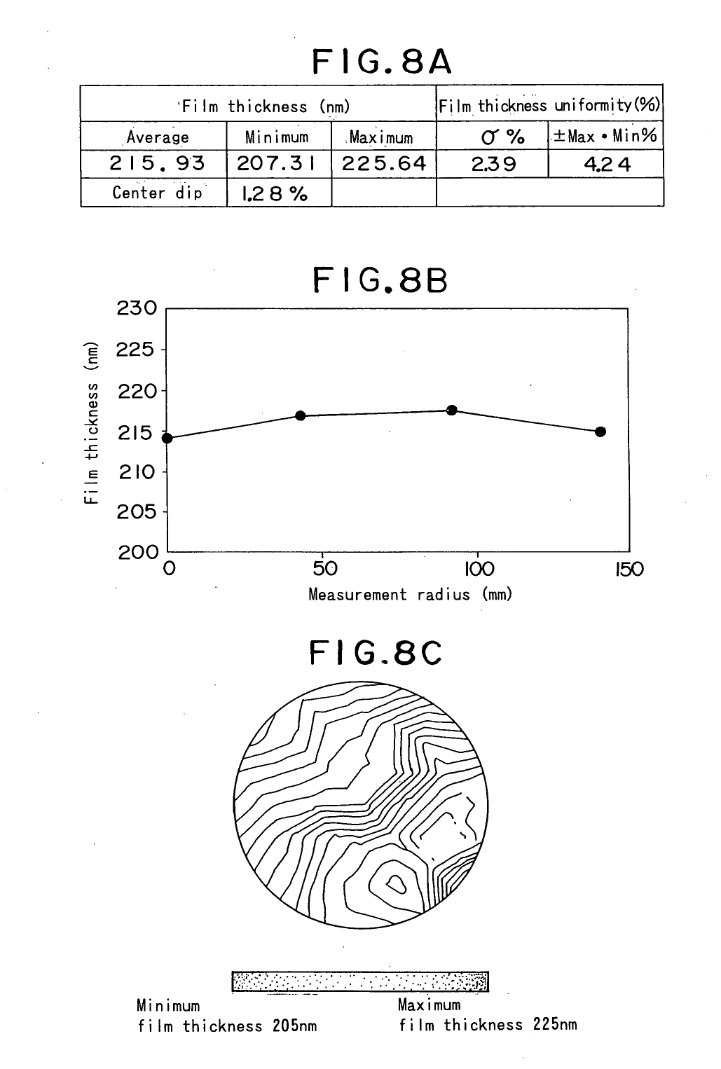

In the state in the purge step where the wafer W is lowered to the wafer carry-in/out position, and assuming that exhausting of the interior of the processing chamber 71 is performed via the main exhaust port 131 and the side exhaust port 134 equally from above, to the side, and from below the wafer W as shown in FIG. 7, then the film thickness distribution of the amorphous silicon film will be non-uniform as shown in FIGS. 8A-8C.

In FIGS. 8A-8C, the σ% and the ±maximum·minimum % is a value expressed by the following formula.

σ=standard deviation (extent of irregularities)/average value×100

±maximum·minimum(%)=(maximum value−minimum value)/2/average value×100

In a state where the exhaust quantity from the main exhaust port 131 is fixed for example at 13 slm, when the exhaust quantity from the side exhaust port 134 is set to a specified quantity for example of 13 slm, then an equivalent exhaust state is attained in the processing chamber 71 from above, to the side, and from below the wafer W.

When a uniform exhaust is obtained in this way, within the processing chamber 71 from above, to the side, and from below the wafer W, the film thickness distribution of the amorphous silicon film formed on the wafer W is thought to be strongly affected by residual components from the disilane gas flowing laterally (horizontal direction) on the wafer W surface so that the distribution of the amorphous silicon film thickness becomes non-uniform as shown in FIGS. 8A-8C.

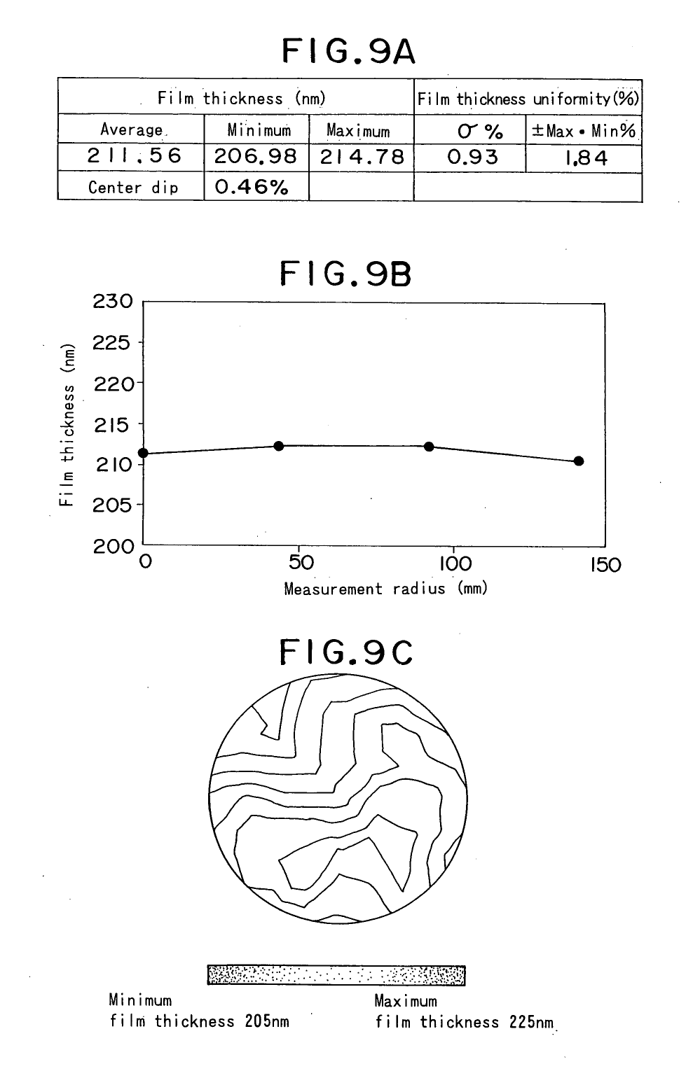

Just as described in FIG. 6A through FIG. 6C, in the purge step of this embodiment, the APC valve 140 is fully opened, and along with drawing a vacuum in the processing chamber 71 at a maximum exhaust quantity of the vacuum exhaust device 132, for example of 20 slm from the main exhaust port 131, the side exhaust valve 136 is opened and a vacuum is drawn at a specified exhaust quantity for example of 13 slm from the side exhaust port 134. Therefore, as shown in FIG. 6A, the exhaust quantity toward above the wafer W is larger than the exhaust quantity toward the side or toward below the wafer W from the side exhaust port 134 so that the film thickness distribution of the amorphous silicon film is uniform as shown in FIGS. 9A-9C.

The present embodiment is structured so that the exhaust flowing toward above the wafer W from the main exhaust port 131 is 1.5 times the exhaust flowing toward the side or below the wafer W from the side exhaust port 134.

In the purge step, when the exhaust quantity flowing to above the wafer W is larger than the exhaust quantity flowing to the side or to below the wafer W from the side exhaust port 134 as shown in FIG. 6A, then the quantity of gas flowing laterally (horizontally) on the surface of the wafer W becomes small so that the effect of residual components from the disilane gas is weakened and the reaction with the residual components can be suppressed. Therefore, the film thickness distribution of the amorphous silicon film becomes uniform as shown in FIGS. 9A-9C.

Moreover, after sufficiently exhausting via the main exhaust port 131 and the side exhaust port 132 in a state where the supply of purge gas G2 is maintained with no stoppages, exhausting is then performed via the chuck exhaust port 137 so that there are virtually no residual components of disilane gas during the exhausting of the interior of the rotating drum 95 via the chuck exhaust port 137, and almost no residual components of disilane gas penetrate inside the rotating drum 95. Therefore, a reaction between the surfaces of such as the heating unit 87 and the wafer elevator device 100 and residual components of disilane gas can be prevented within the rotating drum 95.

The effects rendered by the embodiment are described next.

1) During film-forming in an area with small activation energy such as when using disilane gas to form an amorphous silicon film at low temperature on a wafer, by regulating the exhaust flowing to above the wafer to a larger quantity than to below or to the side of the wafer in the purge step, the exhaust flowing upward can be intensified, and the effect from residual components of disilane gas flowing laterally can be alleviated to render the effect that uniform amorphous silicon film can be formed across the entire surface of the wafer.

2) By making the film thickness distribution of the amorphous silicon film formed on the wafer by disilane gas, uniform across the entire wafer surface, the forming of amorphous silicon film in low-temperature processing using disilane gas can be accelerated, and the IC production yield increased in the IC manufacturing method utilizing this amorphous silicon film, to render the effect of improving the throughput of the IC manufacturing process and the CVD apparatus.

3) In the purge step, the supply of purge gas is maintained with no stoppages, in a state where the exhaust quantity to above the wafer is larger than the exhaust quantity to the side or to below the wafer, and after purging is sufficiently performed, the interior of the rotating drum is exhausted via the chuck exhaust port so that a state can be attained by using the chuck exhaust port for the exhausting, where virtually no residual components of disilane gas remain, therefore rendering the effect that a reaction between surfaces of such as the heating unit and the wafer elevator device and residual components of disilane gas can be prevented within the rotating drum.

4) By preventing the residual components of disilane gas from reacting with surfaces of such as the heating unit and the wafer elevator device within the rotating drum, heater deterioration and corrosion on those members, along with emission of particles from products formed by those reactions can be prevented, to render the effect that unforeseen drops in production yield due to these particles adhering to the wafer can be avoided.

The present invention is not limited to the above embodiments and needless to say, variations of all types not departing from the scope and spirit of the present invention are permitted.

This invention is not limited for example to forming amorphous silicon film on a wafer by utilizing disilane gas at low temperatures, and may be applied to forming amorphous silicon film on a wafer at low temperatures by using monosilane gas.

This invention can also be applied to processes utilizing dopant gas.

In processes utilizing dopant gases such as diboran gas (B₂H₆), for example in processes where forming doped silicon film using diboran gas and silane type gas such as monosilane gas (SiH₄), the dopant gas accelerates the decomposition of the gas, and residual gas tends to remain, so this invention is particularly effective even in such processes.

The present invention may perform only drawing a vacuum, without supplying inert gas during purging.

The substrates for processing are not limited to wafers and may be substrates such as liquid crystal panel and glass substrates utilized in processes for manufacturing LCD devices.

The present invention is not limited to single-wafer type cold wall CVD apparatus and can be applied to overall substrate processing apparatus such as other CVD apparatus.

The preferred aspects of this invention are summarized next.

(1) A semiconductor device manufacturing method comprising the steps of:

loading a substrate into a processing chamber,

mounting the substrate on a support tool in the processing chamber,

processing the substrate mounted on the support tool by supplying process gas into the processing chamber,

purging the interior of the processing chamber after the substrate processing step, and

unloading the processed substrate from the processing chamber after the step of purging the interior of the processing chamber, wherein

in the step of purging the interior of the processing chamber, exhaust is performed toward above the substrate and toward below the substrate in the processing chamber, and the exhaust rate toward above the substrate is set larger than the exhaust rate toward below the substrate.

(2) The semiconductor device manufacturing method according to the first (1) aspect, wherein in the step of purging the interior of the processing chamber, along with performing exhaust toward above the substrate in the processing chamber, exhaust is performed downwards from between an inner wall of the processing chamber and the support tool, and the exhaust rate toward above the substrate is set larger than the exhaust rate downwards from between the inner wall of the processing chamber and the support tool.

(3) The semiconductor device manufacturing method according to the first (1) aspect, wherein the step of purging the interior of the processing chamber is performed in a state where the substrate is lowering and/or a state where the substrate is lowered.

(4) The semiconductor device manufacturing method according to the first (1) aspect, wherein the step of purging the interior of the processing chamber is performed in a state where the support tool is lowering and/or a state where the support tool is lowered.

(5) The semiconductor device manufacturing method according to the first (1) aspect, wherein the step of purging the interior of the processing chamber is performed in a state where the space above the substrate is enlarging and/or is enlarged more than in the step of processing the substrate.

(6) The semiconductor device manufacturing method according to the first (1) aspect, wherein the step of purging the interior of the processing chamber is performed in a state where the substrate is separating and/or is separated from the support tool.

(7) The semiconductor device manufacturing method according to the first (1) aspect, wherein in the step of purging the interior of the processing chamber, after exhaust is performed toward above the substrate and toward below the substrate in the processing chamber, an interior of the support tool is exhausted.

(8) The semiconductor device manufacturing method according to the first (1) aspect, wherein in the step of purging the interior of the processing chamber, before exhaust is performed toward above the substrate and toward below the substrate in the processing chamber, the interior of the processing chamber is exhausted while rotating the substrate mounted on the support tool.

(9) The semiconductor device manufacturing method according to the first (1) aspect, wherein the step of purging the interior of the processing chamber is performed while supplying inert gas into the processing chamber.

(10) A substrate processing apparatus comprising:

a processing chamber for processing a substrate,

a support tool for supporting the substrate in the processing chamber,

an elevator mechanism for raising and lowering the support tool,

a process gas supply system for supplying process gas into the processing chamber,

a purge gas supply system for supplying purge gas into the processing chamber,

a first exhaust port formed higher than an upper side of the support tool in a state where the support tool is lowered for exhausting the interior of the processing chamber,

a second exhaust port formed lower than an upper side of the support tool in a state where the support tool is lowered for exhausting the interior of the processing chamber, and

a controller for controlling to purge the interior of the processing chamber in a state where the support tool is lowering and/or a state where the support tool is lowered, and to make the exhaust rate from the first exhaust port larger than the exhaust rate from the second exhaust port during purging.

1. A semiconductor device manufacturing method comprising the steps of:
loading a substrate into a processing chamber,
mounting the substrate on a support tool in the processing chamber,
processing the substrate mounted on the support tool by supplying process gas into the processing chamber,
purging the interior of the processing chamber after the substrate processing step, and
unloading the processed substrate from the processing chamber after the step of purging the interior of the processing chamber, wherein
in the step of purging the interior of the processing chamber, exhaust is performed toward above the substrate and toward below the substrate in the processing chamber, and the exhaust rate toward above the substrate is set larger than the exhaust rate toward below the substrate.

2. The semiconductor device manufacturing method according to claim 1, wherein in the step of purging the interior of the processing chamber, along with performing exhaust toward above the substrate in the processing chamber, exhaust is performed downwards from between an inner wall of the processing chamber and the support tool, and the exhaust rate toward above the substrate is set larger than the exhaust rate downwards from between the inner wall of the processing chamber and the support tool.

3. The semiconductor device manufacturing method according to claim 1, wherein the step of purging the interior of the processing chamber is performed in a state where the substrate is lowering and/or a state where the substrate is lowered.

4. The semiconductor device manufacturing method according to claim 1, wherein the step of purging the interior of the processing chamber is performed in a state where the support tool is lowering and/or a state where the support tool is lowered.

5. The semiconductor device manufacturing method according to claim 1, wherein the step of purging the interior of the processing chamber is performed in a state where the space above the substrate is enlarging and/or is enlarged more than in the step of processing the substrate.

6. The semiconductor device manufacturing method according to claim 1, wherein the step of purging the interior of the processing chamber is performed in a state where the substrate is separating and/or is separated from the support tool.

7. The semiconductor device manufacturing method according to claim 1, wherein in the step of purging the interior of the processing chamber, after exhaust is performed toward above the substrate and toward below the substrate in the processing chamber, an interior of the support tool is exhausted.

8. The semiconductor device manufacturing method according to claim 1, wherein in the step of purging the interior of the processing chamber, before exhaust is performed toward above the substrate and toward below the substrate in the processing chamber, the interior of the processing chamber is exhausted while rotating the substrate mounted on the support tool.

9. The semiconductor device manufacturing method according to claim 1, wherein the step of purging the interior of the processing chamber is performed while supplying inert gas into the processing chamber.

10. A substrate processing apparatus comprising:
a processing chamber for processing a substrate,
a support tool for supporting the substrate in the processing chamber,
an elevator mechanism for raising and lowering the support tool,
a process gas supply system for supplying process gas into the processing chamber,
a purge gas supply system for supplying purge gas into the processing chamber,
a first exhaust port formed higher than an upper side of the support tool in a state where the support tool is lowered for exhausting the interior of the processing chamber,
a second exhaust port formed lower than an upper side of the support tool in a state where the support tool is lowered for exhausting the interior of the processing chamber, and
a controller for controlling to purge the interior of the processing chamber in a state where the support tool is lowering and/or a state where the support tool is lowered, and to make the exhaust rate from the first exhaust port larger than the exhaust rate from the second exhaust port during purging.
